(19) United States
(12) Patent Application Publication
(10) Pub. No.: US 2009/0245432 A1
(43) Pub. Date: Oct. 1, 2009

(54) Communication system

(76) Inventors: Tadashi Matsumoto, Nomi-shi (JP); Dauch Axel, Dornstetten (DE)

Correspondence Address: WENDEROTH, LIND & PONACK, L.L.P., 1030 15th Street, N.W.,, Suite 400 East, Washington, DC, 20005-1503, US

(21) Appl. No.: 12/379,864

(22) Filed: Mar. 3, 2009

(30) Foreign Application Priority Data
Mar. 26, 2008 (JP) 2008-079470

(51) Int. Cl. H03D 1/00

(52) U.S. Cl. 375/341

(57) ABSTRACT

A communication system receives a signal that is coded using a repetition encoder (2) in a transmitter side, thereafter extended-mapped by an extended mapper (5), and transmitted by a transmitter (6). A demapper (12) demaps the received signal, corresponding to the extended mapping. The decoding unit (15) decodes a result of the demapping, corresponding to the coding using the repetition code. Mutual information between the transmitter coded bits and the log likelihood ratios of the demapping and decoding results is increased by exchanging the likelihood ratio between the demapper (12) and the decoder (15).

### BACKGROUND OF THE INVENTION

1. Field of the Invention

The present invention relates to a communication apparatus, and more particularly channel coding and a mapping method to a modulation signal point in a transmission side and iterative signal processing between a demodulator and a channel decoder for signal detection at a receiver side in a system that transmits and receives digital signal using a digital modulation method through a wired or wireless channel suffering from noise.

2. Description of the Related Art

Various high-performance codes, such as LDPC code and RA code, have been found since the discovery of the turbo code, which approaches the communication channel capacity, in 1993. A technique that is common to these codes is that decoding is carried out by a belief propagation algorithm. Recently, there have been a number of attempts to combine the decoding based on the belief propagation algorithm and other functions necessary for communications in order to obtain further higher performance as a whole.

Among such attempts, a technique called Bit Interleaved Coded Modulation with Iterative Detection (BICM-ID) has attracted attention. In this technique, the probability of a symbol corresponding to a modulation signal point is converted into the probabilities of the bits that constitute the symbol using a priori probability fed back from a decoder, and the probabilities are propagated to the decoder again. (See, for example, L. Hanzo, T. H. Liew, and B. L. Yeap, “Turbo Coding, Turbo Equalization and Space-Time Coding for Transmission over Fading Channels,” John Wiley & Sons, 2002.) The use of this technique makes it possible to generate an error rate threshold (a phenomenon in which error rate can be reduced to a desired value if the reception signal to noise power ratio is greater than a certain value) even in a transmission system that uses multilevel modulation.

However, to generate the error rate threshold, the conventional BICM-ID system requires that the code itself, such as the turbo code and the LDPC code, should be a strong code that approaches the Shannon limit. Therefore, there is a problem that the decoder requires a large processing capability. The reason is that a method called “gray mapping” has been used as the mapping method to an actual multilevel modulation signal point.

In the belief propagation algorithm, iterative processing is performed between a plurality of function blocks. The error probability reduces at every iteration, and finally, a threshold is generated. In this case, it is necessary to evaluate the convergence property in terms of the mutual information exchange in order to evaluate in what way each function block increases the knowledge about the transmitted information. (See, for example, Matsumoto and Ibi, “Turbo Equalization: Fundamentals and Information Theoretic Considerations” IEICE-B, Vol. J90-B, No. 1, pp. 1-16.) In the BICM-ID system, the function blocks correspond to a demodulator (hereinafter referred to as a “demapper”) and a decoder, and the likelihood ratio of each bit that constitutes a modulation symbol point is propagated between the demapper and the decoder.

The convergence property (which indicates not only whether the convergence is fast or slow but also whether a threshold can be generated after iteration) by the iterative processing can be evaluated by mutual information transfer characteristics. For this purpose, Extrinsic Information Transfer Chart (hereinafter abbreviated as an “EXIT chart”) is often used. (See, for example, S. ten Brink, “Convergence Behavior of Iteratively Decoded Parallel Concatenated Codes”, IEEE Trans. on Comm., Vol. 49, No. 10, pp. 1727-1737, October 2001.)

A system such as BICM-ID in which only one of the function blocks (the demapper in the case of BICM-ID) is connected to a channel and the other function blocks (the decoder in the case of BICM-ID) is connected to the former is called a “serially concatenated type” system.

A typical example of the “serially concatenated system” is turbo equalization. Therefore, the EXIT chart will be explained via the turbo equalization system as an example.

FIG. 6 shows an example of the turbo equalization system.

In the turbo equalization system, in this example, a transmitter-side communication apparatus has a bit-wise input 101, an encoder 102, an interleaver 103, a signal mapper 104, and a transmission antenna 105. A receiver-side communication apparatus has a receive antenna 111, a signal detector (equalizer) 112, an adder 113, a deinterleaver 114, a decoder 115, an interleaver 116, and a bit input terminal 117.

Schematically, in the transmitter-side communication apparatus, a bit stream that is input from 101 is encoded by an encoder 102, then interleaved by the interleaver 103, and mapped by the signal mapper 104, and the signal resulted from the encoding is wirelessly transmitted from the transmit antenna 105.

Also schematically, in the receiver-side communication apparatus, the wireless signal from the transmitter side is received by the receive antenna 111 and detected by the signal detector (equalizer) 112. The output therefrom is passed to the adder 113. The result of the addition is deinterleaved by the deinterleaver 114 and decoded by the decoder 115. The output therefrom is obtained from 117, forming a bit stream. In addition, the output from the decoder 115 is interleaved by the interleaver 116 and input to the adder 113 and the signal detector (equalizer) 112. The adder 113 outputs the result obtained by subtracting the input delivered by the interleaver 116 from the output of the signal detector (equalizer) 112.

In the turbo equalization system, the signal detector 112 and the decoder 115 are serially connected, and only the signal detector 112 is connected to the channel, as shown in FIG. 6. The interleaver 116, which randomly changes the positions in time of the bits, and the deinterleaver 114, which performs the reverse operation, are located between the signal detector 112 and the decoder 115. The likelihood ratios of the bits are propagated between the signal detector 112 and the decoder 115. Each of the function blocks (i.e., the signal detector 112 and the decoder 115) updates the likelihood ratios using the input likelihood ratios as a posteriori knowledge of the bit (referred to as “a priori likelihood”) at every iteration, obtains updated likelihood ratios (referred to as extrinsic likelihood ratios), and propagates the obtained updated likelihood ratios to the other.

FIG. 7 shows one example of the EXIT chart for a turbo equalization system.

The horizontal axis corresponds to two parameters. One is the mutual information I_{A,DET} between a priori likelihood ratio that is input to the signal detector 112 and its corresponding transmitted coded bit, and the other is the mutual information I_{E,DEC} between an extrinsic likelihood that is output from the decoder 115 and a corresponding transmitted coded bit. Since their positions in time are the only difference (because of the interleaver 116), their values are the same.

The vertical axis also corresponds to two parameters. One is the mutual information I_{E,DET} between extrinsic likelihood ratio that is output from the signal detector 112 and its corresponding transmitted coded bit, and the other is the mutual information I_{A,DEC} between a priori likelihood that is input to the decoder 115 and its corresponding transmitted coded bit. Since their positions in time are the only difference (because of the deinterleaver 114), their values are the same.

Next, how to analyze convergence property using the EXIT chart will be discussed.

In FIG. 7, “inverted S-shaped” curves 121 to 125 and one curve 131 are depicted. The curve 131 represents the transfer characteristics of the mutual information of the signal detector 112 (wherein the input is represented on the horizontal axis and the output is represented on the vertical axis). The “inverted S-shaped” curves 121 to 125 represent the transfer characteristics of the mutual information of the decoder 115 (wherein the input is represented on the vertical axis and the output is represented on the horizontal axis). The “inverted S-shaped” curves 121 to 125 respectively correspond to coding rate, which is a parameter of the code used; the coding rate increases according to the curve indexes 121, 122, 123, 124, and 125 (i.e., the greater the index numbers such as 121 to 125, the larger the coding rate).

At the first iteration, the mutual information content that is input from the decoder 115 is zero (in other words, the decoder 115 has no knowledge about the transmitted information). However, since the signal detector 112 is connected to the channel, it is possible for the detector to acquire the knowledge about the transmitted information by appropriate signal processing (for example, Minimum Mean Squared Error filtering: MMSE) even when the a priori likelihood from the decoder 115 is zero (i.e., it is possible to increase the mutual information). This value corresponds to the point indicated by reference numeral 141 in the EXIT chart of FIG. 7.

The a priori likelihood ratio having this mutual information is input into the decoder 115. The decoder 115 updates the likelihood ratio, according to a coding rule known to the receiver, using the a priori likelihood ratio (in other words, it increases the mutual information), and obtains an extrinsic likelihood ratio. As an example, assuming that the code with a coding rate of 0.5, indicated by the curve 123, is used, the mutual information corresponding to this extrinsic likelihood ratio corresponds to the point indicated by reference number 142 in the EXIT chart of FIG. 7.

At the second iteration, an a priori likelihood ratio corresponding to the point indicated by reference number 142 in the EXIT chart has already given to the signal detector 112. The signal detector 112 further increases the mutual information by repeating the signal processing using the priori likelihood ratio fed back from the decoder (in this example, it corresponds to the point indicated by reference number 143 in the EXIT chart).

These processes are repeated. Specifically, the mutual information is increased “in a stepwise manner” while the likelihood ratio is propagated between the signal detector curve 131 and a decoder curve (the curve 123 in this example) in the EXIT chart. Such exchange of the mutual information is indicated by reference number 151 in FIG. 7.

Here, a case where the two curves (the signal detector curve and the decoder curve) intersect with each other at a middle point is assumed.

In this case, the mutual information cannot be increased above the value corresponding to the intersecting point. When the curve intersection happens when only relatively low mutual information is achieved (i.e., when the intersection takes place at a point near the vertical axis on the left side of the EXIT chart), impractically bad error rate performance is obtained.

On the other hand, when the two curves are separated with a large gap each other such that they do not intersect with each other, in other words, when using the code having a reverse S-shaped curve that exists at a low level with respect to the given EXIT curve of the signal detector 112, a low error rate can be achieved with a small number of iterations. However, the code with a reverse S-shaped curve at a low level corresponds to a low-rate code, which means that unnecessary bandwidth expansion is required (in other words, the turbo equalization system itself is not making full use of the channel is transmission capability, or a loss of the information rate is being incurred).

Accordingly, if there is no loss of information rate, and if an arbitrarily low error rate can be achieved, it is the state where the system parameters (such as the code and the mapping method) are selected so that the two curves exactly match each other and the two curves do not intersect. In such cases, error rate “threshold” happens.

Next, the convergence property of BICM-ID can be explained in the same way using the EXIT chart as in the case of the turbo equalization system since the BICM-ID is a “serially concatenated” system, and thereby a similarity holds.

That is, when the EXIT curve of the demapper (which is connected to the channel) and the EXIT curve of the decoder intersect each other in iteration process, the mutual information does not increase above that point. On the other hand, when the two EXIT curves are unnecessarily separated each other, the channel's capability is not fully utilized (in other words, the communication channel capacity cannot be achieved asymptotically).

Therefore, in order to achieve an error rate threshold at a received signal-to-noise power ratio such that the coding rate is closed the communication channel capacity, it is necessary to achieve the state in which the two EXIT curves do not separate each other and also there is no intersection. As in the case of the turbo equalization system, and the threshold is generated when the EXIT curves exhibit a behavior close to such tendency.

Here, the mapping method in BICM-ID system is considered.

With the gray mapping, the greater the hamming distance of the vector of the bits that constitute a symbol, the greater the distance of the signal points (referred to as a “Euclidean distance”); therefore, conversion from symbol to bits is possible even only with the received signal sample obtained by the demapper. In other words, each bit after conversion contains information of transmitted coded bits in a large quantity (in other words, the mutual information between the demapper output and the transmitted coded bits is large) even when there is no a priori likelihood fed back from the decoder. Therefore, the EXIT curve of the demapper with the gray mapping does not show a steep slope. Therefore, a code having an EXIT curve of the decoder which suitably fits such a comparatively flat EXIT curve of the demapper (that causes a small gap but still no intersection) is a turbo code or an LDPC code.

However, in the cases of the turbo and the LDPC codes, the codes themselves require a large number of iterative processing within the decorder, which necessitates a large processing power. In other words, there is a problem that a large processing complexity for decoding is required when the code is designed to fit for the gray mapping.

The invention has been accomplished in view of the conventional unpreferable circumstances, and it is an object to provide a communication apparatus that can match the EXIT curve of the demapper and the EXIT curve of the decoder (in other words, the EXIT curves match as closely as possible each other, and the intersecting point appears in a region near the vertical axis on the right side of the EXIT chart) in a very simple method (in other words, with a very low decoding complexity).

### SUMMARY OF THE INVENTION

In order to accomplish the objective described above, the invention employs the following configuration in a communication apparatus that receives a signal transmitted from a transmitter.

Here, in a transmitter side, a signal that is coded by repetition coding and is thereafter extended-mapped by an extended mapping rule is transmitted by the transmitter.

Specifically, in the receiver side, the demapper convers a received signal corresponding to a symbol of the extended mapping. The decoder decodes the encoded bit stream, obtained as result of the demapping, according to the coding rule, which is repetition coding. The communication system is comprised of a function to increase the mutual information between the transmitted coded bit and the extrinsic log likelihood ratios by exchanging (propagating) the mutual information between the demapper and the decoder.

Therefore, by using a combination of repetition code and extended mapping, it becomes possible to match the EXIT curve of the demapper and the EXIT curve of the decoder (in other words, the EXIT curves are matched closely each other and the intersecting point appears in a region near the vertical axis on the right side of the EXIT chart) in a very simple method (in other words, with avery easy to decode). Thereby, an error rate threshold can be generated.

Here, the transmitter is the communication system may have both the transmit and receive functions, or it may have the transmit function only.

Likewise, the receiver in the communication system may have both the transmit and receive functions, or it may have the receive function only.

In addition, the communication may be either wired communication or wireless communication. It is also possible to use this invention both in wired communication and wireless communication.

Aside from the demapper and the decoder, a signal processor performs the algorithm for the demapping and decoding to increase the mutual information between the transmitted coded bits and the log likelihood ratios. The information to be propagated between the demapper and decorder should not necessarily be likelihood ratios.

For example, it is possible to use extrinsic probability of each bit.

For example, the transmitter may have an interleaver, and the receiver may have a deinterleaver corresponding to the interleaver. In this case, another interleaver having the same functionality as that of the foregoing the interleaver may need to be located on the feedback path between the demapper and the decoder in the receiver.

In a preferred embodiment, the communication system according to the invention employs the following configuration.

Specifically, the mapping rule is an extended version of quadrature phase shift keying (QPSK) that uses the following labeling: the bit patterns 000 and 101 are assigned to a first symbol, 010 and 111 are assigned to a second symbol, 001 and 100 are assigned to a third symbol, and 011 and 110 are assigned to a fourth symbol (for example, a mapping in which 3 bits are assigned to 1 symbol, as shown in FIG. 2A); another mapping rule where bit patterns 0100, 1110, 0010, and 1000 are assigned to the first symbol, 1101, 1011, 0111, and 0001 are assigned to the second symbol, 1010, 1100, 0000, and 0110 are assigned to the third symbol, and 1111, 0101, 1001, and 0011 are assigned to the fourth symbol (for example, a mapping in which 4 bits are assigned to 1 symbol, as shown in FIG. 2B); the mapping rule may be used where the bit patterns 10011, 10110, 01011, 10101, 01110, 01101, 11111, and 00111 are assigned to the first symbol, 00100, 00001, 00010, 11010, 11001, 10000, 01000, and 11100 are assigned to the second symbol, 10111, 01111, 00110, 11101, 00101, 00011, 11110, and 11011 are assigned to the third symbol, and 10010, 00000, 11000, 10001, 01010, 10100, 01001, and 01100 are assigned to the fourth symbol (for example, a mapping in which 5 bits are assigned to 1 symbol, as shown in FIG. 2C).

In another preferred embodiment, the extended mapping rule comprised of a mapping rule to a modulation signal point in which 3 or more bits are assigned per 1 symbol, the mapping being a quadrature phase shift keying (QPSK) such that the mutual information related to an output from the demapping unit becomes greatest when the mutual information between the coded bits and extrinsic likelihood ratios propagated from the decoder is greatest (for example, when the mutual information is very close to 1 in the case of binary representation of information).

As described above, by using combinations of repetition codes and extended mapping, the invention makes it possible to match the EXIT curve of the demapper and the EXIT curve of the decoder (in other words, the EXIT curves are not separated unnecessarily each other and the intersecting point appears in a region near the vertical axis on the right side of the EXIT chart) in a very simple method (in other words, without requiring heavy decoding complexity). Thereby, an error rate threshold can be generated.

### BRIEF DESCRIPTION OF THE DRAWINGS

FIG. 1 is a diagram illustrating a configuration example of a communication system according to one possible embodiment of the invention, wherein FIG. 1A is a diagram illustrating a configuration example of the transmitter and FIG. 1B is a diagram illustrating a configuration example of the receiver.

FIGS. 2A, 2B, and 2C are the diagrams illustrating examples of extended mapping methods.

FIG. 3 is a graph illustrating an example of EXIT curve for extended mapping.

FIG. 4 is a graph illustrating an example of an EXIT chart.

FIG. 5 is a graph illustrating an example of bit error rate performance versus received signal-to-noise power ratio.

FIG. 6 is a diagram illustrating an example of a turbo equalization system.

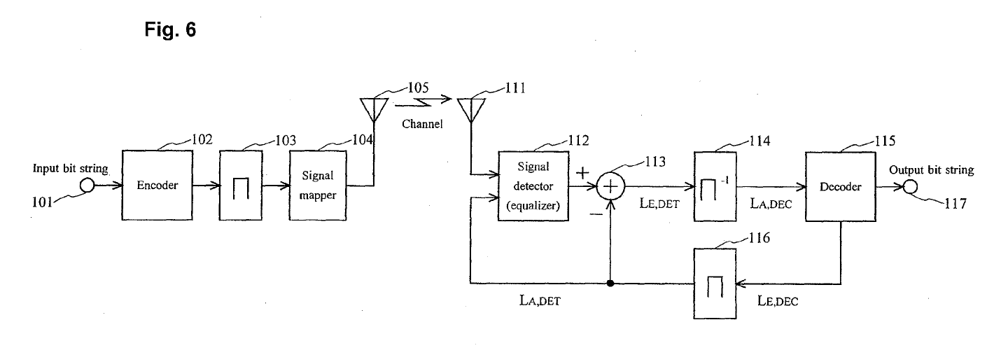

FIG. 7 is a graph illustrating an example of an EXIT chart for the turbo equalization system.

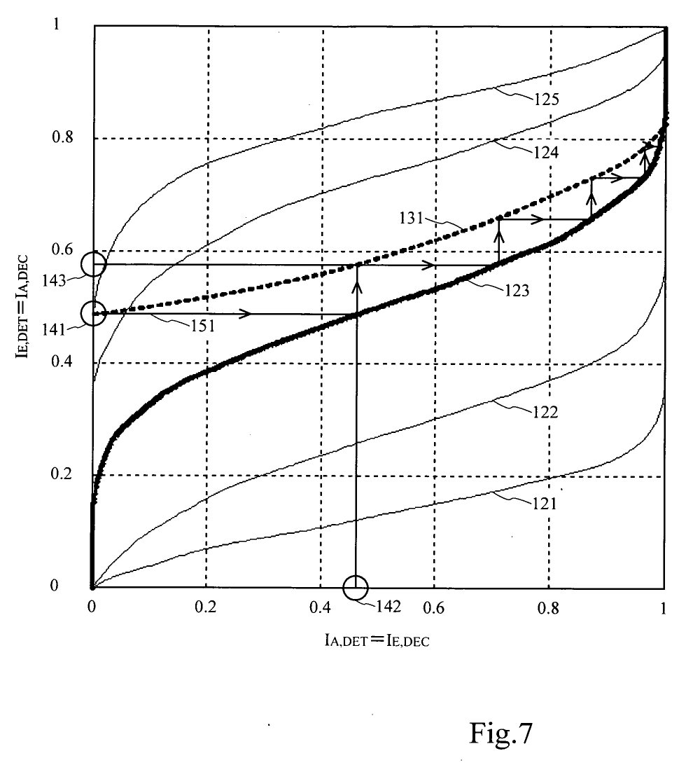

### DESCRIPTION OF THE PREFERRED EMBODIMENTS

Preferred embodiments of the invention will be described with reference to the drawings.

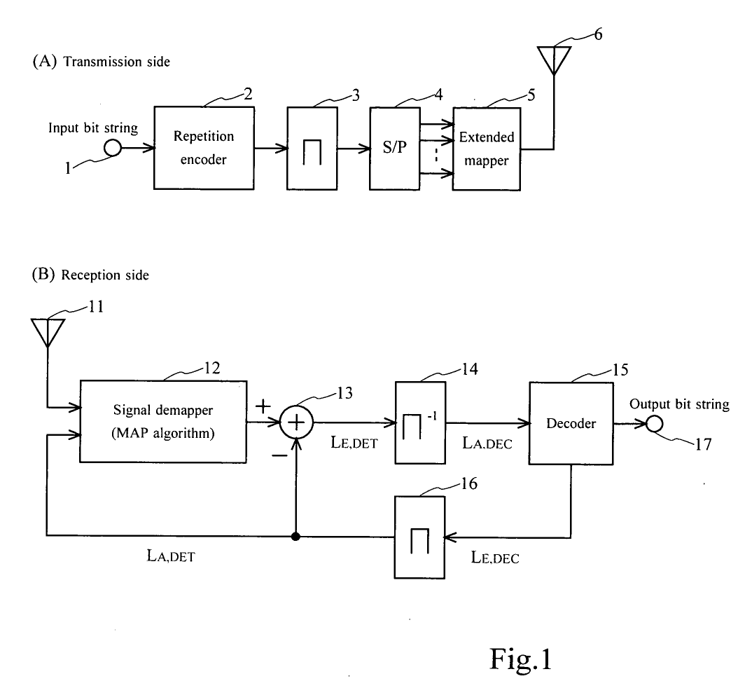

FIG. 1A shows a configuration example of a transmitter according to a possible embodiment of the invention, and FIG. 1B shows a configuration example of a receiver according to a possible embodiment of the invention.

It should be noted that although the transmitter and the receiver are illustrated separately in this example, it is possible that a communication system is comprised of both the transmit and the receive functions.

As shown in FIG. 1A, the transmitter of this example is comprised of a bit input 1, a repetition encoder 2, an interleaver 3, a serial/parallel (S/P) converter 4, an extended mapper 5, and a transmission antenna 6.

As shown in FIG. 1B, the receiver of this example is comprised of a receive antenna 11, a signal demapper (MAP algorithm) 12, an adder 13, a deinterleaver 14, a decoder 15, an interleaver 16, and a bit output 17.

Schematically, in the transmitter, a bit stream to be transmitted is coded by the repetition coder 2, interleaved by the interleaver 3, and subjected to serial-parallel conversion by the serial-parallel converter 4 and extended-mapped by the mapper 5. The signal thus obtained is wirelessly transmitted from the transmit antenna 6.

Also schematically, in the receiver, the wireless signal from the transmitter is received by the receive antenna 11 and processed by the signal demapper (MAP algorithm) 12. The output therefrom is passed to the adder 13. The result of the addition is deinterleaved by the deinterleaver 14 and decoded by the decoder 15. The output from the decoder 15 is interleaved by the interleaver 16 and is input into the adder 13 and the signal demapper (MAP algorithm) 12. The adder 13 outputs the result obtained by subtracting the input delivered by the interleaver 16 from the output of the signal demapper (MAP algorithm) 12.

Hereinbelow, the process performed in the communication system of this example will be detailed.

To generate an error rate threshold at a received signal-to-noise power ratio at which a given coding rate is very close to the communication channel capacity, the EXIT curve of the demapper 12 and the EXIT curve of the decoder 15 have to be closely matched. A strong code such as the turbo code has been required when gray mapping is used. This invention makes it possible to match the two EXIT curves using a simpler code by changing the mapping method.

Accordingly, this example focuses on the foregoing point.

Specifically, a mapping rule with low bit separability is used on purpose without enough high decoder feed back mutual information, though the mapping rule can achieve high bit separability when the likelihood ratio of each bit propagated from the decoder 15 increases. Specifically, the BICM-ID is constructed using a system in which multiple bit labeling vectors are assigned to each symbol (a system called “Extended Mapping,” see, for example, P. Henkel, “Extended Mappings for Bit-Interleaved Coded Modulation,” Proc. of the 17th PIMRC, Helsinki). This makes it possible to use a code with a lower coding rate without reducing the frequency utilization efficiency of the overall transmission system.

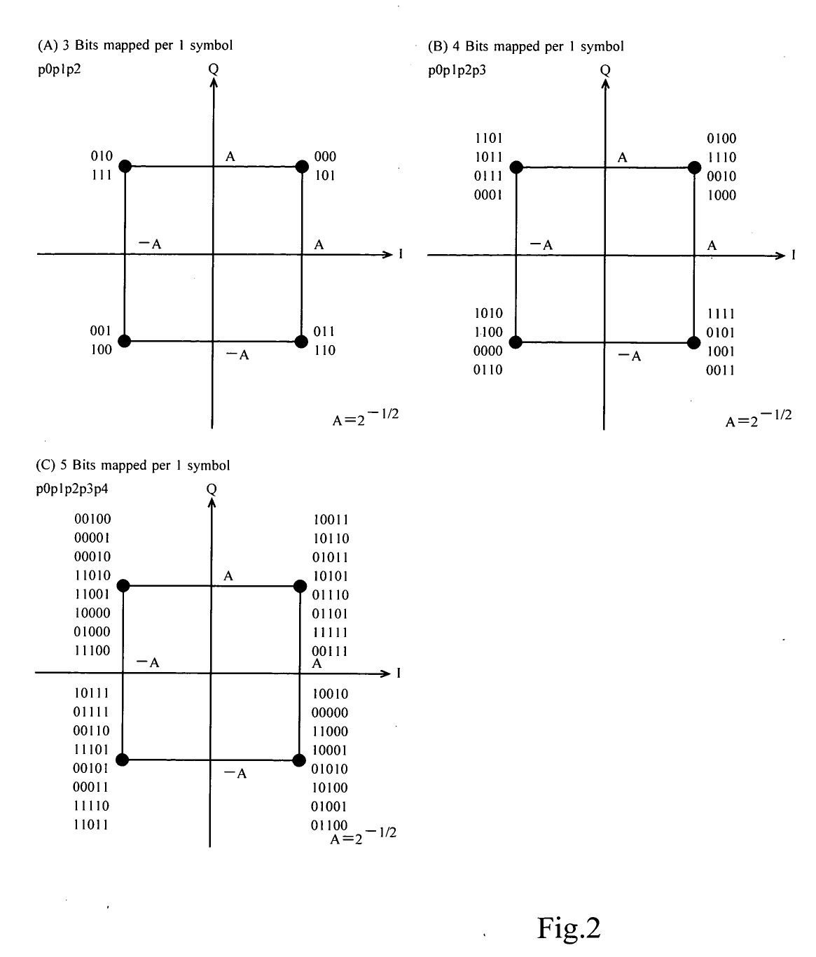

FIGS. 2A, 2B, and 2C show examples of mapping methods (extended mapping methods) for quadrature phase shift keying (hereinafter abbreviated as “QPSK”) signal points at which the mutual information of the output from the demapper 12 becomes greatest when the mutual information corresponding to the likelihood ratio propagated from the decoder 15 is 1 (the maximum value in the case of binary representation of information).

FIG. 2A shows a case in which 3 bits are mapped per 1 symbol, FIG. 2B shows a case in which 4 bits are mapped per 1 symbol, and FIG. 2C shows a case in which 5 bits are mapped per 1 symbol.

Here, the parameters corresponding to FIGS. 2A, 2B, and 2C are numbers of bit labeling patterns mapped to the each symbol (i.e., spectral efficiency).

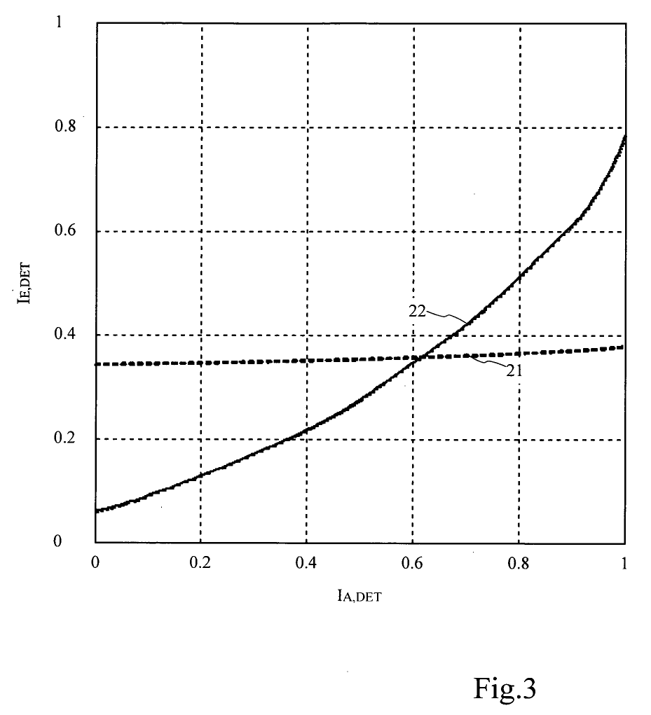

FIG. 3 shows one example of the EXIT chart of the demapper 12 in the case the mapping rules shown in FIGS. 2A, 2B, and 2C are used. Specifically, it shows a curve 21 that is an EXIT curve in the case of using a gray mapping and also shows a curve 22 that is an EXIT curve in the case of using an extended mapping.

Referring to FIG. 3, it will be understood that when the mutual information I_{A,DET} corresponding to the likelihood ratio propagated from the decoder 15 is 0, the mutual information I_{E,DET} of the output from the demapper 12 is far smaller in the case of extended mapping than that in the case of gray mapping. This means that when this mapping method is used, the error probability is high even though the demapper 12 itself may convert a symbol to a bit. On the other hand, when the mutual information propagated from the decoder 15 is 1, the mutual information of the output from the demapper 12 is significantly greater in the case of extended mapping than that in the case of gray mapping. This corresponds to the fact that the right end of the EXIT curve rises when the left end thereof falls because the mapping method does not change the spectral efficiency itself (that is, the area below the EXIT curve does not depend on the mapping method).

As a result, the EXIT curve of the demapper 12 for the extended mapping shows a steep slope. Therefore, for example, if the turbo code or the LDPC code is used, an intersecting point appears in a region close to the vertical axis on the left side of the EXIT chart. Accordingly, when these codes are combined with the extended mapping, only a high error rate can be obtained, and no threshold is generated.

This suggests that a code with a steep EXIT curve slope needs to be used. An example of such a code showing an EXIT curve with a steep slope is a repetition code, which is the most simple code. The decoding of a repetition code is very simple and does not require high computational complexity such as required by the decoder for the turbo code and the LDPC code.

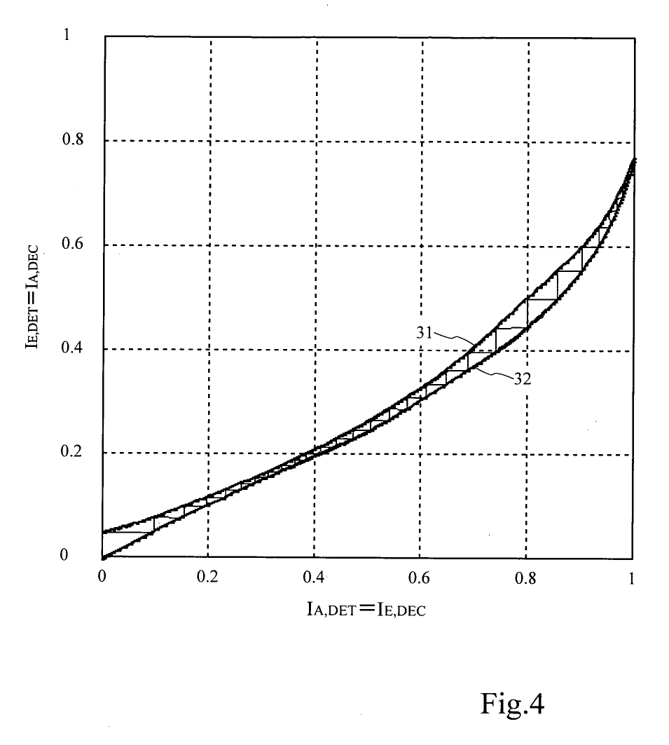

FIG. 4 shows an example of an EXIT chart 31 of the demapper 12 for the extended mapping (in which the horizontal axis represents the mutual information of the input and the vertical axis represents the mutual information of the output) and an example of an EXIT chart 32 of the decoder 15 for the repetition code (in which the vertical axis represents the mutual information of the input and the horizontal axis represents the mutual information of the output).

As shown in FIG. 4, the two curves 31 and 32 are very close to each other, and the intersecting point appears at a location very close to the vertical axis at the right hand side. This suggests that error rate threshold is generated.

That is, when the signal-to-noise power ratio of the channel is small, the two curves 31 and 32 intersect with each other in a region close to the vertical axis at the left hand side of the EXIT chart. As the signal-to-noise power ratio is increased gradually, the EXIT curve 31 of the demapper 12 moves upward gradually, and suddenly, the two curves 31 and 32 do not intersect with each other for almost all the values on the horizontal axis (in reality, they intersect with each other at a point very close to the vertical axis at the right hand side). This state corresponds to the phenomenon that the error rate suddenly becomes small, in other words, a threshold is generated.

As one example, the signal-to-noise power ratio at which the threshold is generated is 1.2 dB when combining a QPSK with 3 bit extension (i.e., 5 bits/symbol) and a 5-time repetition code.

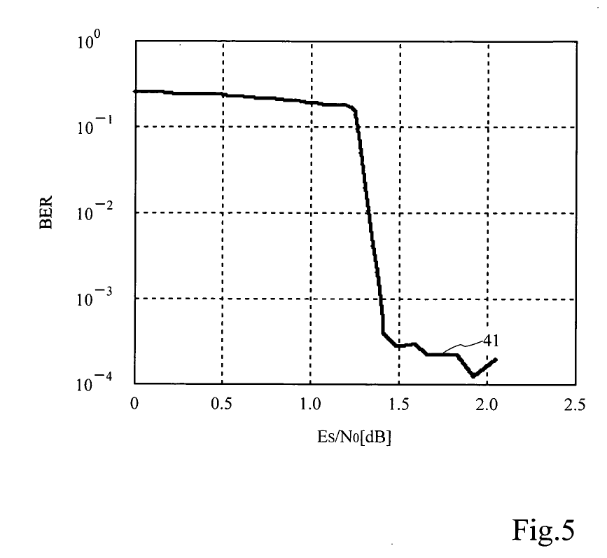

FIG. 5 shows an example (curve 41) of bit error rate (BER) versus received signal-to-noise power ratio (Es/No). The horizontal axis represents the received signal-to-noise power ratio, and the vertical axis represents the error rate.

Referring to FIG. 5, it will be understood that a threshold is generated at a location where the signal-to-noise power ratio is around 1.2 dB.

Next, the operation of the communication system of this example shown in FIGS. 1A and 1B will be explained.

In the transmitter, the information bit stream to be transmitted is encoded into a repetition code by the repetition encoder 2. The coding rate is set at a reciprocal number of the spectral efficiency of the modulation system obtained by applying the extended mapping (for example, at a coding rate of ⅕ in the case of using a QPSK extended by 3 bits).

The position in time of each coded bit of the output from the repetition encoder 2 (the result of the repetition coding) is randomized by the interleaver 3.

After serial/parallel conversion of 1 input m (for example, m=3, 4, or 5 corresponding to FIG. 2A, 2B, or 2C) output is performed by the serial-parallel converter 4, and the output from the interleaver 3 is mapped to modulation signal points of extended mapping, corresponding to the parallel data pattern, by the extended mapper 5. For example, when the signal constellations shown in FIGS. 2A, 2B, and 2C are used, it is possible to transmit 3, 4, and 5 bits/symbol, respectively, mapped to the QPSK modulation signal points.

In the receiver, a received signal sample is converted into a bit likelihood ratio by the demapper 12. The signal processing algorithm (referred to as “demapping”) for this process is called a maximum a posteriori probability (MAP) algorithm (for details, see, for example, P. Henkel, “Extended Mappings for Bit-Interleaved Coded Modulation,” Proc. of the 17th PIMRC, Helsinki).

As described above, the signal constellations shown in FIGS. 2A, 2B, and 2C are optimized on the condition that the mutual information fed back from the decoder 15 is 1. In other words, under this condition, the likelihood of the signal separability can be maximized compared to other mapping systems.

After subtracting the a priori log likelihood ratio that is input to the demapper 12 by the adder 13 from the bit likelihood ratio that is the output from the demapper 12, the bit likelihood ratio is input into the deinterleaver 14 that is opposite operation to that of the interleaver.

The output from the deinterleaver 14 is input into the repetition code decoder 15, and the likelihood ratio of each coded bit is updated in the decoder 15.

The likelihood ratio that has been updated by the decoder 15 is interleaved by the interleaver 16. The likelihood ratio is thereafter input (fed back) into the demapper 12 as an a priori likelihood ratio and at the same time input into the adder 13.

Since this a priori likelihood ratio is used by the demapping algorithm for separating bits comprising each symbol, the separability is increased (in other words, mutual information of the demapper 12 output that is higher than the value obtained at the first can be obtained).

Such processes are iteration.

As described above, in the signal repeated transmission system of this example, the transmitter transmits a signal that has been coded using a repetition code and subjected to extended mapping, and the receiver carries out demapping (demodulation) and decoding for the reception signal and performs exchange of likelihood ratios between the signal demapper 12 and the decoder 15 iteratively. Thereby, the mutual information is increased.

The signal transmission system of this example employs one of the mapping methods shown in FIGS. 2A, 2B, and 2C as the extended mapping method.

Thus, the communication system of this example can simplify the process of BICM-ID at the receiver remarkably. In addition, it is possible to generate an error rate threshold even though the repetition code, which is a very simple code, is used. Thereby, the complicated process requiring iteration within the decoder, such as the turbo code and the LDPC code, can be eliminated.

For example, a bit rate equivalent to 32-quadrature amplitude modulation (32 QAM) can be accomplished by extending the mapping of the quadrature phase shift keying (QPSK) by 3 bits (5 bits per symbol). This means that the QPSK with 3 bit extension, which does not incurr amplitude variation, may be used in place of the 32 QAM, which has amplitude variations. As a result, the load to the communication system (transmitter-receiver chain) (such as the amount of power consumption by the transmitter and the sensitivity to various impairment factors) can be reduced significantly.

It should be noted that the transmitter of this example is configured as follows. The repetition encoding is performed by the repetition coder 2. Interleaving is performed by the interleaver 3. Extended mapping is performed by the extended mapper 5. Signal transmission is performed through the transmission antenna 6.

On the other hand, the receiver of this example is configured as follows. Signal reception is performed by the receiver having the antenna 11. Demapping is performed by the signal demapper (MAP algorithm) 12. Addition is performed by the adder 13. Deinterleaving is performed by the deinterleaver 14. Decoding is performed by the decoder 15. Interleaving is performed by the interleaver 16. The likelihood ratio of each bit is propagated from the signal demapper 12 via the adder 13 and the deinterleaver 14 to the decoder 15. On the feedback path, the likelihood ratio of each bit is propagated from the decoder 15 via the interleaver 16 to the signal demapper 12. The process is repeated, whereby the mutual information between the transmitted coded bits and the log likelihood ratio is increased.

Herein, the configurations of the systems according to the invention are not necessarily limited to those described above, and various configurations may be employed. The invention in practice may be implemented in the form of a method or a system for executing a process according to the invention, such as digital signal processor and a storage medium for recording the program for the invention. The invention may also be implemented in the form of various systems.

The applicable fields of the invention are not necessarily limited to those described above, and the invention may be applied to various fields.

Furthermore, as various processes performed in the systems according to the invention, it is possible to employ a configuration in which, in a hardware resource containing such as a processor and a memory, the processor is controlled by executing a control program stored in a ROM (Read Only Memory). Alternatively, the respective function means for performing the processes are constructed by respective independent hardware circuits.

Moreover, the invention may also be implemented as a storage medium that is computer-readable medium, such as a floppy (registered trademark) disk and a CD (Compact Disc)-ROM, that stores the above-described control program, and the program (itself). The process according to the invention may be executed by allowing the control program to be input from the storage media to a computer that executes the program.

What is claimed is:

1. A communication system that receives a signal that is coded by repetition code at a transmitter, thereafter extended-mapped by an extended mapper and transmitted by a transmission unit, comprising:
a demapping unit for demapping the reception signal corresponding to the extended mapping; and
a decoding unit for decoding a result of the demapping by the demapping unit, corresponding to the coding using the repetition code,
the communication system comprising a function to increase mutual information between transmitted coded bits and log likelihood ratios obtained as a result of the demapping and decoding by exchanging the likelihood ratios between the demapper and the decoder.

2. The communication system according to claim 1, wherein:
the extended mapping is a quadrature phase shift keying that uses one of the following:
a first mapping in which 000 and 101 are assigned to a first symbol, 010 and 111 are assigned to a second symbol, 001 and 100 are assigned to a third symbol, and 011 and 110 are assigned to a fourth symbol;
a second mapping in which 0100, 1110, 0010, and 1000 are assigned to the first symbol, 1101, 1011, 0111, and 0001 are assigned to the second symbol, 1010, 1100, 0000, and 0110 are assigned to the third symbol, and 1111, 0101, 1001, and 0011 are assigned to the fourth symbol; or
a third mapping in which 10011, 10110, 01011, 10101, 01110, 01101, 11111, and 00111 are assigned to the first symbol, 00100, 00001, 00010, 11010, 11001, 10000, 01000, and 11100 are assigned to the second symbol, 10111, 01111, 00110, 11101, 00101, 00011, 11110, and 11011 are assigned to the third symbol, and 10010, 00000, 11000, 10001, 01010, 10100, 01001, and 01100 are assigned to the fourth symbol.
